(19) United States
(12) Patent Application Publication
(10) Pub. No.: US 2007/0023796 A1
(43) Pub. Date: Feb. 1, 2007

(54) PINNING LAYER FOR PIXEL SENSOR CELL AND METHOD THEREOF

(75) Inventors: James W. Adkisson, Jericho, VT (US); John J. Ellis-Monaghan, Grand Isle, VT (US)

Correspondence Address: IBM MICROELECTRONICS;INTELLECTUAL PROPERTY LAW, 1000 RIVER STREET, 972 E, ESSEX JUNCTION, VT, 05452, US

(73) Assignee: INTERNATIONAL BUSINESS MACHINES CORPORATION, Armonk, NY (US)

(21) Appl. No.: 11/161,224

(22) Filed: Jul. 27, 2005

(51) Int. Cl. H01L 31/113; H01L 31/062

(52) U.S. Cl. 257/290; 257/292; 438/48; 257/E27.133

(57) ABSTRACT

A novel pixel sensor cell structure and method of manufacture. The pixel sensor cell includes a collection well region of a first conductivity type and a pinning layer formed in a substrate. The pinning layer includes a first impurity region of a second conductivity type and a second impurity region of the second conductivity type. The first and second impurity regions can be independently formed to affect multiple parameters of the pixel sensor cell.

### FIELD OF THE INVENTION

The present invention relates generally to semiconductor pixel sensor cells, and more particularly, to a pixel sensor cell having an improved pinning layer, and process therefore.

### BACKGROUND OF THE INVENTION

CMOS image sensors are beginning to replace conventional CCD sensors for applications requiring image pick-up such as digital cameras, cellular phones, PDA (personal digital assistant), personal computers, and the like. Advantageously, CMOS image sensors are fabricated by applying present CMOS fabricating process for semiconductor devices such as photodiodes or the like, at low costs. Furthermore, CMOS image sensors can be operated by a single power supply so that the power consumption can be restrained lower than that of CCD sensors, and further, CMOS logic circuits and like logic processing devices are easily integrated in the sensor chip and therefore the CMOS image sensors can be miniaturized.

Current CMOS image sensors comprise an array of pixel sensor cells, which are used to collect light energy and convert it into readable electrical signals. Each pixel sensor cell comprises a photosensitive element, such as a photodiode, photo gate, or photoconductor overlying a doped region of a substrate for accumulating photo-generated charge in an underlying portion thereof. A read-out circuit is connected to each pixel cell and often includes a diffusion region for receiving charge from the photosensitive element, when read-out. Typically, this is accomplished by a transistor device having a gate electrically connected to the floating diffusion region. The imager may also include a transistor, having a transfer gate, for transferring charge from the photosensitive element to the floating diffusion region, and a transistor for resetting the floating diffusion region to a predetermined charge level prior to charge transfer.

As shown in FIG. 1, a typical CMOS pixel sensor cell 10 includes a pinned photodiode 20 having a pinning layer 18 doped p-type and an underlying collection well 17 lightly doped n-type. Typically, pinned photodiode 20 is formed on top of a p-type silicon substrate 15, or a p-type epitaxial silicon layer or p-well surface layer, having a lower p-type concentration than pinning layer 18. N region 17 and p region 18 of photodiode 20 are typically spaced between an isolation region 19 and a charge transfer transistor gate 25 which is surrounded by thin spacer structures 23a,b. The photodiode 20 thus has two p-type regions 18 and 15 having a same potential so that the n region 17 is fully depleted at a pinning voltage (Vp). The pinned photodiode 20 is termed “pinned” because the potential in the photodiode 20 is pinned to a constant value, Vp, when the photodiode 20 is fully depleted. In operation, light coming from the pixel is focused down onto the photodiode and electrons collect at the n type region 17. When the transfer gate structure 25 is operated, i.e., turned on, the photo-generated charge 24 is transferred from the charge accumulating lightly doped n-type region 17 via a transfer device surface channel 16 to a floating diffusion region 30 which is doped n+type.

In a conventional CMOS imager cell, p-type pinning layer 18 is electrically coupled to p-type substrate 15 by a doped p-type region 29. Since substrate 15 is typically connected to a ground potential (i.e. 0 V), pinning layer 18 is also at the ground potential. If a poor electrical connection between the substrate 15 and the pinning layer 18 is formed, the pinning layer 18 may float to another potential value, thus preventing the collection well 17 from fully depleting when the transfer gate structure 25 is turned on. Additionally, since the surface of the substrate 15 in the area where the photodiode 20 is formed has a relatively high number of defects due to, for example, substrate surface roughness, process induced damage, dangling bonds which introduce trap states, etc., the pinning layer 18 also serves to passivate the substrate surface of the photodiode 20 which reduces dark current generation.

In conventional processes for fabricating the pinning layer 18 in the prior art pixel sensor cell 10 shown in FIG. 1, a problem is that an end portion of the pinning layer 18 somewhat overlaps the transfer gate structure 25. Since the pinning layer 18 is biased to a ground potential, a relatively large potential barrier to charge transfer between the collection well 17 and the transfer device channel 16 is created. For example, a typical process includes ion implantation of boron (B) atoms to fabricate the p-type pinning layer 18. The amount of boron atoms implanted must be controlled since the boron atoms will laterally diffuse in subsequent hot process steps (i.e. high temperature anneals) due to their relatively low atomic mass resulting in the end portion of the pinning layer overlapping the transfer gate structure 25.

Replacing boron with a heavier p-type dopant such as, for example, indium (In) to form the pinning layer 18 reduces dopant out diffusion, however damage to the upper surface of the substrate 15 in the region where the pinning layer 18 is formed increases due to ion implantation of the larger indium atoms. The damage to the substrate 15 results in increased dark current for the conventional CMOS image sensor cell.

Another problem is the interaction of the p-type dopant in the pinning layer 18 with the n-type collection well 17. Boron is known to “channel” (i.e. boron atoms move through openings in the crystal) in silicon resulting in p-type dopant in the n-type collection well 17. This results in variations in the concentration distribution of the impurity dopant in the n-type collection well which can adversely affect the properties of the photodiode 20.

It would thus be highly desirable to provide a novel pixel sensor cell and method of manufacture whereby problems associated with the pinning layer of the conventional pixel sensor cell are reduced without adversely affecting the performance of the photodiode and the transfer gate.

### SUMMARY OF THE INVENTION

The invention addresses a novel pixel sensor cell structure and method of manufacture. Particularly, a pixel sensor cell is fabricated whereby problems associated with the pinning layer of the conventional pixel sensor cell are reduced without adversely affecting the performance of the photodiode and the transfer gate.

According to an embodiment of the invention, the pixel sensor cell includes a collection well region of a

first conductivity type formed in a substrate and a pinning layer formed in the substrate comprising a first impurity region of a second conductivity type and a second impurity region of the second conductivity type. This improves the control of the readout of the charge of the pixel sensor cell as the ability of the pinning layer to produce a potential barrier to charge transfer is reduced.

### BRIEF DESCRIPTION OF THE DRAWINGS

The objects, features and advantages of the present invention will become apparent to one skilled in the art, in view of the following detailed description taken in combination with the attached drawings, in which:

FIG. 1 depicts a CMOS image sensor pixel array 10 according to the prior art;

FIG. 2 illustrates a pixel sensor cell 100 of the present invention; and

FIGS. 3-5 depict, through cross-sectional views, process steps according to an embodiment of the present invention for forming the pixel sensor cell 100 and resulting in the structure shown in FIG. 2.

### DETAILED DESCRIPTION OF THE PREFERRED EMBODIMENTS

Embodiments of the invention are described herein below in terms of a “pixel sensor cell”. It is noted that the term “pixel sensor cell” is used to generally refer to any type of sensor cell which is capable of converting incident electromagnetic radiation into an electrical signal. An example of a pixel sensor cell according to the invention includes a pixel sensor cell that is capable of detecting optical wavelengths of electromagnetic radiation and is commonly referred to as an “image sensor”. An image sensor fabricated using CMOS technology is commonly referred to as a “CMOS image sensor”.

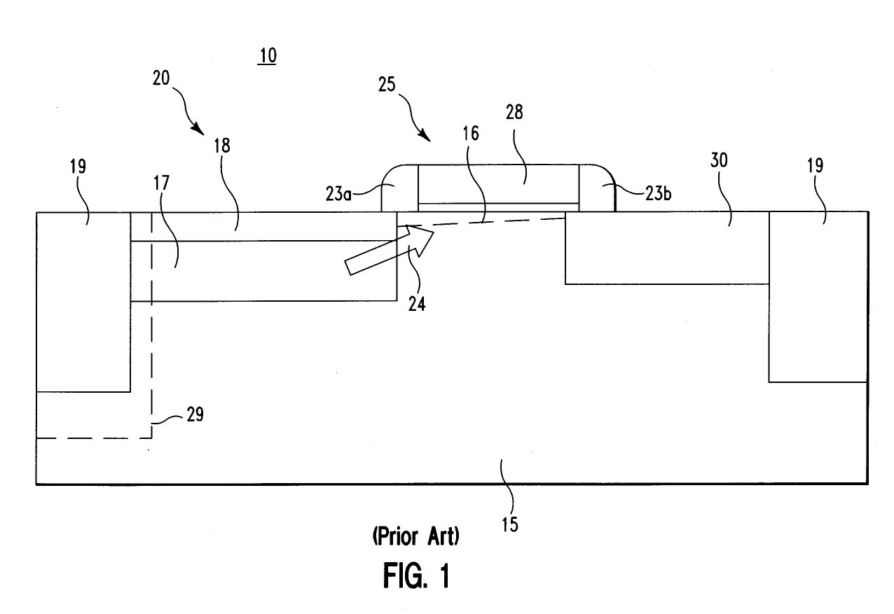

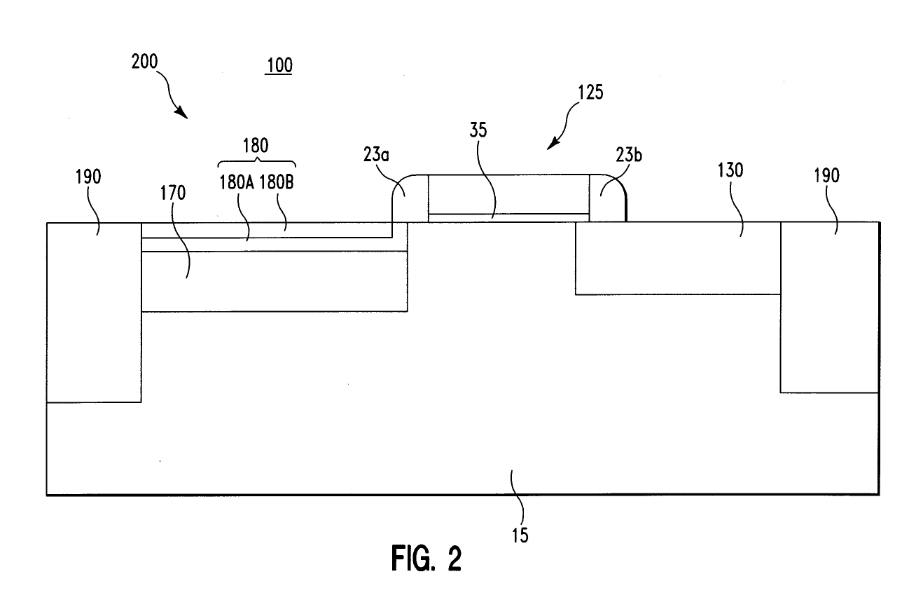

FIG. 2 illustrates pixel sensor cell 100 according to an embodiment of the present invention. As shown in FIG. 2, the pixel sensor cell 100 includes a transfer gate 125 formed on top of a gate dielectric material layer 35 which is formed on top of a semiconductor substrate 15. Between one side of the transfer gate 125 and isolation region 190 is a photodiode 200 comprising a surface pinning layer 180 doped with material of a first conductivity type, e.g., p type material dopant, and a charge collection well region 170 doped with material of a second conductivity type, e.g., n type material dopant, formed directly underneath the pinning layer 180. The pinning layer 180 is electrically coupled to the substrate 15 by doped p-type region 29 (see FIG. 1) or by doped p-type region (not shown) formed along a sidewall of isolation region 190 (described in commonly assigned U.S. patent application Ser. No. 10/905,043 filed Dec. 13, 2004 and entitled A MASKED SIDEWALL IMPLANT FOR IMAGE SENSOR, the whole contents of which is incorporated by reference as if fully set forth herein) so that the pinning layer 180 and the substrate 15 are at the same voltage potential, typically ground potential. Abutting the other side of the transfer gate 125 is a gate diffusion region 130 doped with material of a second conductivity type, e.g., n type material dopant.

P-type pinning layer 180 comprises at least two regions 180A and 180B. Pinning layer region 180A is doped with a first material of the first conductivity type, e.g. indium, having a relatively low diffusivity in the substrate 15. Pinning region 180B is doped with a second material of the first conductivity type, e.g. boron, having a relatively higher diffusivity in the substrate 15 than the first material. Indium region 180A reduces channeling of p-type dopant into the collection well region 170 since indium atoms do not channel as readily as boron atoms. Therefore, the need for off-angle ion implants to form the pinning layer 180 is reduced. Additionally, indium region 180A reduces out diffusion of p-type dopant under transfer gate 125 hence improving charge transfer of the pixel sensor cell due to reduced barrier potential interference from the pinning layer 180.

A pinning layer comprising only an indium dopant region has been avoided in conventional pixel sensor cells due to the increase in dark current created by damage in the substrate from ion implantation of the relatively large indium atoms. However, according to the present invention, indium region 180A is nested within boron region 180B. In other words, indium region 180A region is formed substantially adjacent to an upper surface of the substrate 15, and boron region 180B extends beyond and surrounds the indium region 180A in the collection well region 170. By forming boron region 180B surrounding indium region 180A, the boron region 180B extends beyond a substantial amount of the defects created in the substrate 15 by indium region 180A. Thus, the impact of the indium induced substrate defects on the performance of the pixel sensor cell 100 is reduced compared to the condition of using only indium as the pinning layer dopant.

An advantage of the pinning layer 180 according to the present invention is it allows the pinning layer region 180A to be formed independent of the pinning layer 180B in order to affect multiple device parameters of the photodiode 200. For example, the pinning layer region 180A can be optimized to passivate the surface of the substrate to reduce dark current in the photodiode 200 while the pinning layer region 180B can be optimized to provide a desired value for a parameter of the photodiode 200 such as photodiode capacitance.

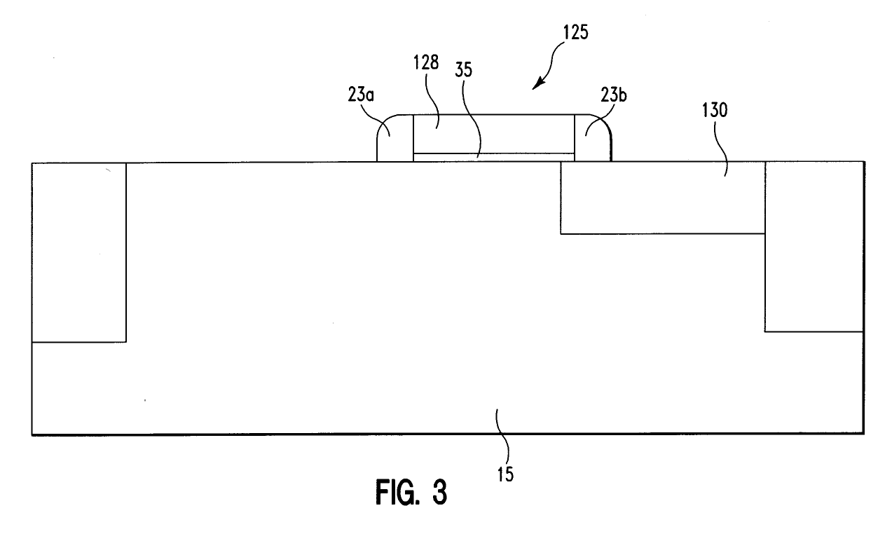

The method to fabricate a pixel sensor cell according to an embodiment of the invention will be described with reference to FIGS. 3-5. As shown in FIG. 3, there is provided a substrate 15 which may be a bulk semiconductor including, for example, Si, SiGe, SiC, SiGeC, GaAs, InP, InAs and other semiconductors, or layered semiconductors such as silicon-on-insulators (SOI), SiC-on-insulator (SiCOI) or silicon germanium-on-insulators (SGOI). For purposes of description, substrate 15 is a Si-containing semiconductor substrate of a first conductivity type, e.g., lightly doped with p-type dopant material such as boron or indium (beryllium or magnesium for a III-V semiconductor), to a standard concentration ranging between about 1×10¹⁴ atoms per cm³ to about 1×10¹⁶ atoms per cm³. Next, transfer gate structure 125 is formed using standard processing techniques known in the art. For example, a dielectric material layer (not shown) is formed by standard deposition or growth techniques atop the substrate 15 that will form the eventual transfer gate dielectric 35. The dielectric layer is typically formed to a thickness ranging between 35 Å to 100 Å and may comprise suitable gate dielectric materials including but not limited to: an oxide (e.g., SiO₂), a nitride (e.g., silicon nitride) an oxynitride (e.g., Si oxynitride), N₂O, NO, ZrO₂, or other like materials. The dielectric layer is formed on the surface of the Si-containing semiconductor substrate 15 using conventional thermal oxidation or by a suitable deposition process such as chemical vapor deposition, plasma-assisted chemical vapor deposition, evaporation, sputtering and other like deposition processes. Although it is not shown, it is understood that the dielectric layer may comprise a stack of dielectric materials.

Next, a gate layer (not shown) is deposited above the dielectric material layer using conventional deposition processes including, but not limited to: CVD, plasma-assisted CVD, sputtering, plating, evaporation and other like deposition processes (e.g., a low pressure CVD). The gate layer may be comprised of any conductor including metals, silicides, or polysilicon. For purposes of description, an intrinsic polysilicon layer is used. The intrinsic polysilicon layer structure is formed atop the dielectric material layer surface to a thickness ranging between about 1 kÅ to 2 kÅ, however, the thickness may be outside this range. It is understood that for proper operation, a polysilicon gate layer must be doped with the second conductivity type, e.g. n-type, to a concentration in the range of about 1×10¹⁸ atoms per cm³ to about 1×10²⁰ atoms per cm³. This may be accomplished by the standard practice of utilizing the source/drain implants or by predoping the polysilicon before etch, or by using insitu doped polysilicon.

Regardless of whether or not the formed gate polysilicon layer is doped, e.g., subsequently by ion implantation or, in-situ doped and deposited, the transfer gate 125 is then formed to result in the structure shown in FIG. 3, whereby a photo lithographic process is used to define the transfer gate dielectric 35 and the transfer gate conductor 128. This step is not illustrated since there are many different ways how the lateral size and shape of the gate can be defined. Typically, an etch window is provided in a photo-resist mask (not shown), and one or more etch processes are performed, e.g., a reactive ion etch process, that is optimized to ensure proper etching of the doped polysilicon gate layer and dielectric material layer or dielectric layer stack. Chemical Mechanical Polish (CMP) techniques can also be used to define the transfer gate structure, and may be the preferred method when using metal gates.

In a further step (not shown), gate sidewall spacers 23a, b are formed at either side of the transfer gate 125 by conventional deposition processes known in the art, and may comprise any conventional oxide or nitride (e.g., Si₃N₄) or oxide/nitride, and then they are etched by RIE or another like etch process. The thickness of spacers 23a, b may vary, but typically they have a thickness of from about 10 nm to about 150 nm.

An n-type gate diffusion region 130 at one side of the transfer gate is then formed. This step (not shown) comprises forming a photoresist layer and patterning and etching an ion implantation mask according to techniques known in the art to form a mask edge approximately coincident with the gate edge or as close as possible given alignment tolerances, to provide an opening allowing the implantation of n-type dopant material, such as phosphorus, arsenic or antimony, at a concentration sufficient to form the n+-type gate diffusion region 130 as shown in the FIGS. up to the edge of the spacer 23b as shown in the structure depicted in FIG. 3. The active n+-type dopant material is ion implanted at a dose sufficient to provide concentrations in the gate diffusion region 130 ranging between about 1×10¹⁸ atoms per cm³ and about 1×10²⁰ atoms per cm³. It is noted that gate diffusion region 130 can be formed at other points in the process, for example, after formation of the photodiode 200 (described herein below).

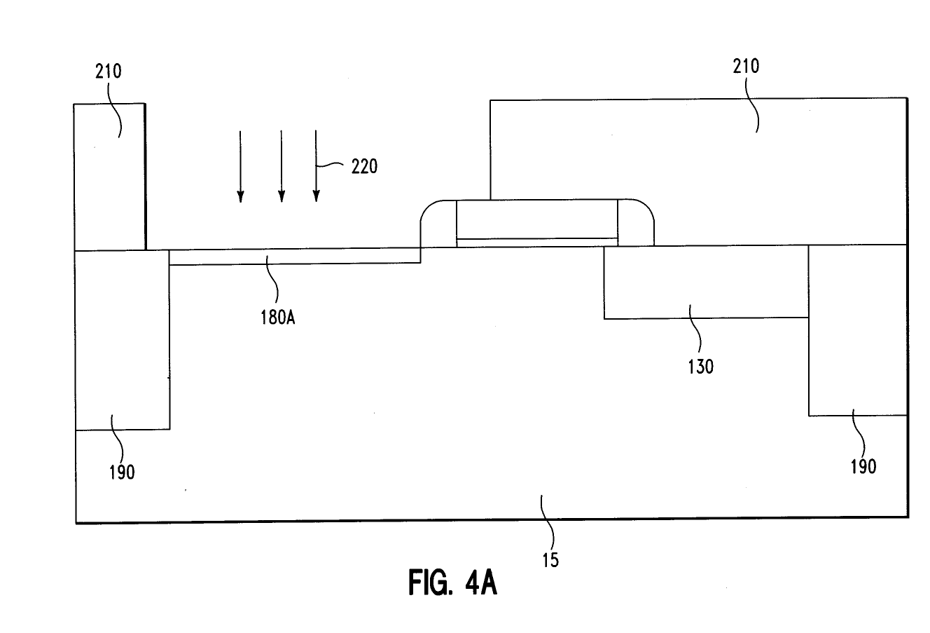

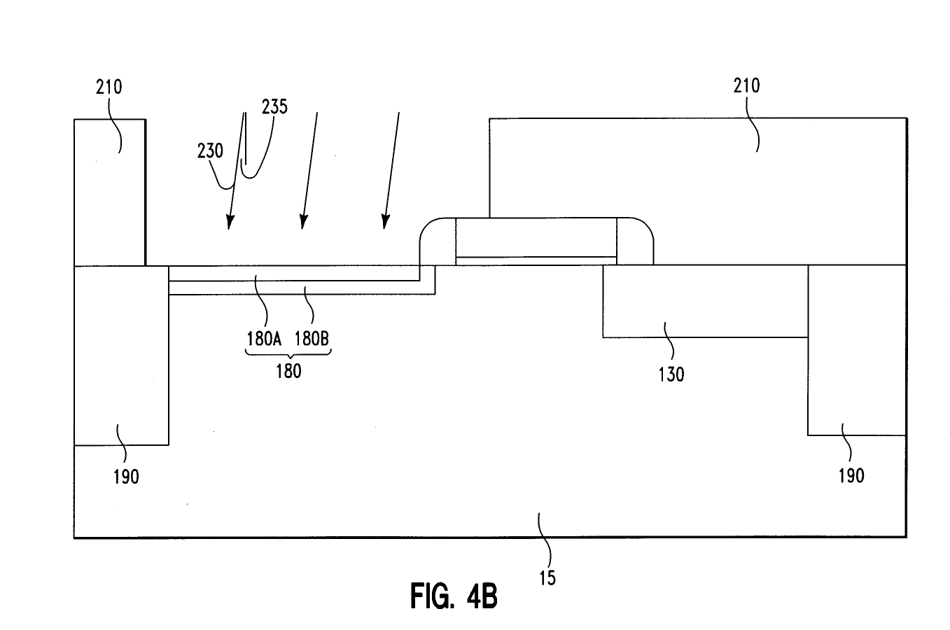

Formation of the pinning layer 180 according to an embodiment of the invention will be described with reference to FIGS. 4A and 4B. Referring to FIG. 4A, a masking layer such as photoresist is formed atop substrate 15 and is patterned to form ion implantation mask 210 according to techniques known in the art to provide an opening to an area between an edge of the transfer gate 125 and isolation region 190, e.g., STI region, where the charge accumulation region of the photodiode 200 is to be formed. This opening permits the implantation of ions 220 of a first p-type dopant material having a relatively low diffusivity in the silicon substrate 15. An example of the first p-type dopant material is indium. Indium can be ion implanted at a concentration sufficient to form the p-type pinning layer region 180A. Preferably, indium is ion implanted at conditions of: a dose ranging between about 1×10¹² atoms per cm² and about 1×10¹⁴ atoms per cm²; an ion implant energy ranging between about 20 keV to about 500 keV; and, an ion implant angle at substantially a vertical angle (e.g. 90 degrees) with reference to the surface of the substrate 15. In a more preferred embodiment, indium is ion implanted at conditions of: a dose ranging between about 5×10¹² atoms per cm² and about 5×10¹³ atoms per cm²; an ion implant energy ranging between about 100 keV to about 200 keV; and, an ion implant angle at substantially a vertical angle (e.g. 90 degrees) with reference to the surface of the substrate 15. A resulting concentration of indium in the silicon substrate 15 is about 1×10⁷ atoms per cm³ to about 5×10¹⁸ atoms per cm³.

Referring to FIG. 4B, the same ion implantation mask 210 can be used to ion implant ions 230 of a second p-type dopant material having a relatively higher diffusivity in the silicon substrate 15. An example of the second p-type dopant material is boron. Boron can be ion implanted at a concentration sufficient to form the p-type pinning layer region 180B. Preferably, boron can be ion implanted at conditions of: a dose ranging between about 5×10¹² atoms per cm² and about 5×10³ atoms per cm²; an ion implant energy ranging between about 2 keV to about 25 keV; and, an ion implant angle 235 of about 3 degrees to about 30 degrees relative to the surface of the substrate 15. In a more preferred embodiment, boron can be ion implanted at conditions of: a dose ranging between about 1×10³ atoms per cm² and about 3×10¹³ atoms per cm²; an ion implant energy ranging between about 5 keV to about 10 keV; and, an ion implant angle 235 of about 5 degrees to about 10 degrees relative to the surface of the substrate 15. By performing the boron ion implant 230 at an angle 235 channeling of boron in the substrate 15 is reduced, thus improving performance of the photodiode 200. The resulting concentration of boron in the silicon substrate 15 is about 5×10¹⁷ atoms per cm³ to about 1×10¹⁹ atoms per cm³, with a typical concentration being about 3×10¹⁸ atoms per cm³.

It is noted that the composite doped pinning layer 180 (i.e. regions 180A and 180B) according to the invention results in reduced out diffusion under the transfer gate 125 compared to the conventional boron-only doped pinning layer. Even though boron pinning layer region 180B extends beyond indium pinning layer region 180A due to out diffusion of the boron, the boron pinning layer region 180B does not out diffuse under the transfer gate 125 as much as a conventional boron-only doped pinning layer. Thus, the barrier potential interference caused by the pinning layer 180 is reduced in the pixel sensor cell 100 of the present invention.

It should be understood that, alternatively, either one or both of the p pinning layer regions 180A and 180B may be formed by other techniques such as, for example, a gas phase doping process, or a solid phase doping process where a p-type dopant is diffused into the substrate 15 from an in-situ doped layer or a doped oxide layer deposited over the area where photodiode 200 is to be formed. Regions 180A and 180B also may be formed subsequent to or before forming the collection well region 170 described herein after.

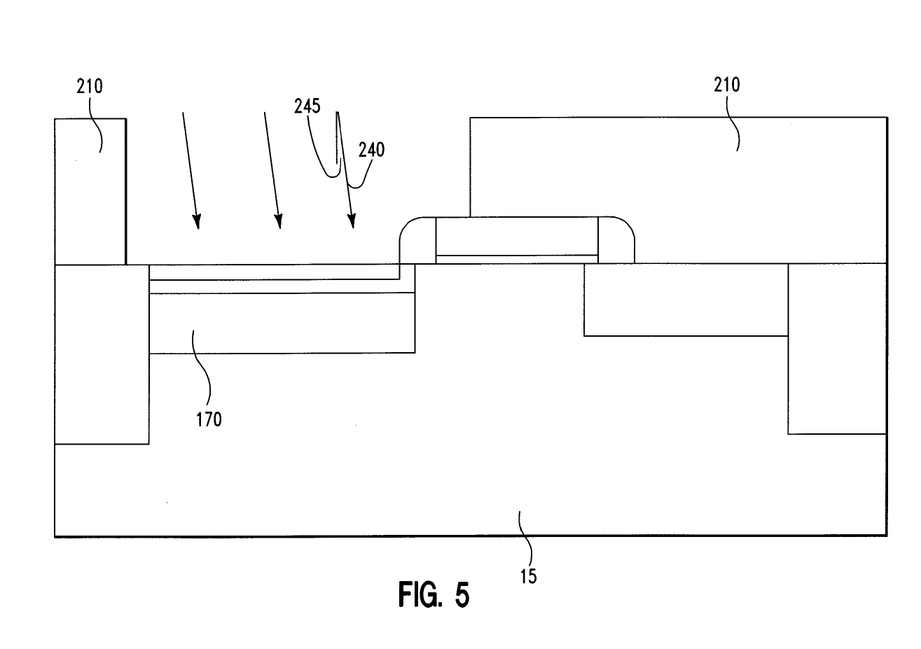

Referring to FIG. 5, using the same ion implantation mask 210 (or, optionally, a different ion implantation mask), an ion implantation process is performed to implant dopant material of the second conductivity type, e.g., n-type dopant material, such as phosphorus, arsenic or antimony, to form the charge collection well region 170 beneath the p type pinning layer 180. The n-type dopant material can be ion implanted at higher energy levels to form the n-type collection well region 170 of the photodiode 200 as shown in the FIGS. The n-type dopant material can be ion implanted at a dose sufficient to provide a concentration in the substrate 15 ranging between about 1×10¹⁶ atoms per cm³ and about 1×10¹⁸ atoms per cm³. The collection well region 170 for collecting photo-generated electrons may be formed by a single or multiple implants to tailor the profile of the n-type region 170. For example, collection well region 170 can be formed by an angled ion implant 240 at an angle 245 of about 3 degrees to about 30 degrees relative to the surface of the substrate, preferably at an angle 245 of about 5 degrees to about 10 degrees relative to the surface of the substrate.

While there has been shown and described what is considered to be preferred embodiments of the invention, it will, of course, be understood that various modifications and changes in form or detail could readily be made without departing from the spirit of the invention. It is therefore intended that the invention be not limited to the exact forms described and illustrated but should be constructed to cover all modifications that may fall within the scrope of the appended claims.

What is claimed is:

1. A pixel sensor cell comprising:
a substrate;
a collection well region of a first conductivity type formed in said substrate; and
a pinning layer formed in said substrate comprising a first impurity region of a second conductivity type and a second impurity region of the second conductivity type.

2. The pixel sensor cell of claim 1, wherein said first impurity region comprises a first material having a first diffusivity rate in said substrate and said second impurity region comprises a second material having a second diffusivity rate in said substrate greater than said first diffusivity rate.

3. The pixel sensor cell of claim 1, wherein said first impurity region is formed substantially adjacent to an upper surface of said substrate, and said second impurity region extends beyond said first impurity region to surround said first impurity region in said collection well region.

4. The pixel sensor cell of claim 1, wherein said first impurity region comprises indium.

5. The pixel sensor cell of claim 4, wherein a concentration of indium in said pinning layer is from about 1×10⁷ atoms per cm³ to about 5×10¹⁸ atoms per cm³.

6. The pixel sensor cell of claim 1, wherein said second impurity region comprises boron.

7. The pixel sensor cell of claim 6, wherein a concentration of boron in said pinning layer is from about 5×10¹⁷ atoms per cm³ to about 1×10¹⁹ atoms per cm³.

8. A CMOS image sensor having at least one pixel sensor cell, the at least one pixel sensor cell comprising:
a substrate;
a collection well region of a first conductivity type formed in said substrate; and
a pinning layer formed in said substrate comprising a first impurity region of a second conductivity type and a second impurity region of the second conductivity type.

9. The CMOS image sensor of claim 8, wherein said first impurity region is nested within said second impurity region.

10. The CMOS image sensor of claim 9, wherein said first impurity region is formed substantially adjacent to an upper surface of said substrate, and said second impurity region extends beyond said first impurity region to surround said first impurity region in said collection well region.

11. The CMOS image sensor of claim 8, wherein said first impurity region comprises indium.

12. The CMOS image sensor of claim 11, wherein a concentration of indium in said pinning layer is in the range of about 1×10¹⁷ atoms per cm³ to about 5×10¹⁸ atoms per cm³.

13. The CMOS image sensor of claim 8, wherein said second impurity region comprises boron.

14. The CMOS image sensor of claim 13, wherein a concentration of boron in said pinning layer is in the range of about 5×10¹⁷atoms per cm⁻³ to about 1×10¹⁹atoms per cm⁻³.

15. A method of forming a pixel sensor cell comprising the steps of:
providing a substrate;
forming a collection well region of a first conductivity type in said substrate; and forming a pinning layer in said substrate comprising a first impurity region of a second conductivity type and a second impurity region of the second conductivity type.

16. The method of claim 15, wherein said first impurity region comprises a first material having
a first diffusivity rate in said substrate and said second impurity region comprises a second material having a second diffusivity rate in said substrate greater than said first diffusivity rate.

17. The method of claim 15, wherein said step of forming said pinning layer comprises the steps of:
ion implanting a first impurity to a first depth to form said first impurity region; and
ion implanting a second impurity to a second depth greater than said first depth to form said second impurity region.

18. The method of claim 17, wherein said step of ion implanting said first impurity comprises ion implanting indium at a dose from about 1×10¹² atoms per cm² to about 1×10¹⁴ atoms per cm².

19. The method of claim 17, wherein said step of ion implanting said second impurity comprises ion implanting boron at a dose from about 5×10¹² atoms per cm² to about 5×10¹³ atoms per cm².

20. The method of claim 19, wherein said step of ion implanting said second impurity comprises ion implanting boron at an angle of about 3 degrees to about 30 degrees relative to an upper surface of said substrate.
